(19) United States
(12) Patent Application Publication
(10) Pub. No.: US 2010/0001300 A1
(43) Pub. Date: Jan. 7, 2010

(54) COPACKING CONFIGURATIONS FOR NONPOLAR GaN AND/OR SEMIPOLAR GaN LEDs

(75) Inventors: JAMES W. RARING, Goleta, CA (US); DANIEL F. FEEZELL, Goleta, CA (US); MARK P. D'EVELYN, Goleta, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: Soraa, Inc., Goleta, CA (US); Kaai, Inc., Goleta, CA (US)

(21) Appl. No.: 12/491,176

(22) Filed: Jun. 24, 2009

Related U.S. Application Data
(60) Provisional application No. 61/076,596, filed on Jun. 27, 2008.
(60) Provisional application No. 61/075,339, filed on Jun. 25, 2008.

(51) Int. Cl. H01L 33/00

(52) U.S. Cl. 257/90; 257/E33.056

(57) ABSTRACT

A packaged light emitting device. The device has a substrate member comprising a surface region. The device has a substrate member comprising a surface region. The device also has two or more light emitting diode devices overlying the surface region according to a specific embodiment. At least a first of the light emitting diode device is fabricated on a semipolar GaN containing substrate and at least a second of the light emitting diode devices is fabricated on a nonpolar GaN containing substrate. In a preferred embodiment, the two or more light emitting diode devices emits substantially polarized emission. Of course, there can be other variations, modifications, and alternatives.

### CROSS-REFERENCE TO RELATED APPLICATIONS

This application claims priority to U.S. Provisional Application Ser. No.:61/075,339 (Attorney Docket No.: 027364-001400US) filed Jun. 25, 2008, and U.S. Provisional Application Ser. No. 61/076,596 (Attorney Docket No. 027364-001600US) filed Jun. 27, 2008, commonly assigned, and incorporated by reference herein in their entirety for all purpose.

### BACKGROUND OF THE PRESENT INVENTION

The present invention relates generally to lighting techniques. More specifically, embodiments of the invention include techniques for combining different colored LED devices, such as blue and yellow, fabricated on bulk semipolar or nonpolar materials. Merely by way of example, the invention can be applied to applications such as white lighting, multi-colored lighting, lighting for flat panel display, other optoelectronic devices, and the like.

In the late 1800's, Thomas Edison invented the light bulb. The conventional light bulb, commonly called the “Edison bulb,” has been used for over one hundred years. The conventional light bulb uses a tungsten filament enclosed in a glass bulb sealed in a base, which is screwed into a socket. The socket is coupled to AC power or DC power. The conventional light bulb can be found commonly houses, buildings, and outdoor lightings, and other areas requiring light. Unfortunately, drawbacks exist with the conventional Edison light bulb. That is, the conventional light bulb dissipates much thermal energy. More than 90% of the energy used for the conventional light bulb dissipates as thermal energy. Additionally, the conventional light bulb routinely fails often due to thermal expansion and contraction of the filament element.

To overcome some of the drawbacks of the conventional light bulb, fluorescent lighting has been developed. Fluorescent lighting uses an optically clear tube structure filled with a halogen gas. A pair of electrodes is coupled between the halogen gas and couples to an alternating power source through a ballast. Once the gas has been excited, it discharges to emit light. Often times, the optically clear tube is coated with phosphor materials. Many building structures use fluorescent lighting and, more recently, fluorescent lighting has been fitted onto a base structure, which couples into a standard socket.

Solid state lighting techniques have also been used. Solid state lighting relies upon semiconductor materials to produce light emitting diodes, commonly called LEDs. At first, red LEDs were demonstrated and introduced into commerce. Red LEDs use Aluminum Indium Gallium Phosphide or AlInGaP semiconductor materials. Most recently, Shuji Nakamura pioneered the use of InGaN materials to produce LEDs emitting light in the blue color range for blue LEDs. The blue colored LEDs lead to innovations such as the BlueRay™ DVD player, solid state white lighting, and other developments. Other colored LEDs have also been proposed, although limitations still exist with solid state lighting. Further details of such limitations are described throughout the present specification and more particularly below.

From the above, it is seen that techniques for improving optical devices is highly desired.

### BRIEF SUMMARY OF THE INVENTION

According to the present invention, techniques for lighting are provided. More specifically, embodiments of the invention include copackaging configurations for different colored LED devices, such as blue and yellow, blue, green, and red, or blue, green, yellow, and red, fabricated on bulk semipolar GaN, bulk nonpolar GaN, bulk polar GaN, and/or polar heteroepitaxial substrates, and arsenide or phosphide containing materials. In addition, configurations for copackaging the said LED devices with silicon integrated circuits with or without feedback loops are provided. Merely by way of example, the invention can be applied to applications such as white lighting, multi-colored lighting, lighting for flat panels, other optoelectronic devices, and the like.

In a specific embodiment, the present invention provides a packaged light emitting device. The device has a substrate member comprising a surface region. The device also has two or more light emitting diode devices overlying the surface region according to a specific embodiment. At least a first of the light emitting diode device is fabricated on a semipolar GaN containing substrate and at least a second of the light emitting diode devices is fabricated on a nonpolar GaN containing substrate. In a preferred embodiment, the two or more light emitting diode devices emits substantially polarized emission. Of course, there can be other variations, modifications, and alternatives.

In yet an alternative specific embodiment, the present invention provides one or more of the following alternative devices and related methods. A semipolar LED copackaged with a nonpolar LED is provided according to a specific embodiment. In a preferred embodiment, the blue LED is provided on a nonpolar GaN and yellow is on provided on semipolar GaN or alternatively the blue LED is provided on a semipolar GaN and yellow is provided on nonpolar GaN. This embodiment would still emit substantially polarized light since both constituents emit polarized light. In alternative embodiments, at least two nonpolar GaN LEDs are copackaged or at least two semipolar GaN LEDs are copackaged. In yet an alternative embodiment, the invention provides for any combination of LEDs substantially free from any phosphides or arsenides (eg AlInGaP), such as copackaging polar with nonpolar and/or semipolar GaN LEDs. In some embodiments, the polar GaN LEDs are homoepitaxial, that is, grown on a bulk GaN substrate by an analogous method used to fabricate the homoepitaxial nonpolar or semipolar GaN LEDs. In another set of embodiments, the polar GaN LEDs are heteroepitaxial, grown on a non-GaN substrate such as sapphire, SiC, MgAl₂O₄ spinel, according to methods that are known in the art. In yet an alternative embodiment, the present invention provides for copackaging semipolar and/or nonpolar LED chips with arsenide or phosphide containing LED chip such as AlInGaP. In still other embodiments, the present invention provides for copackaging polar with nonpolar and/or semipolar GaN-based LED chips with at least one arsenide or phosphide containing LED chip.

In some embodiments, at least one nonpolar GaN device is fabricated on an m-plane GaN substrate. In other embodiments, at least one nonpolar GaN device is fabricated on an a-plane GaN substrate. In some embodiments, at least one semipolar GaN device is fabricated on a (11-22) GaN substrate. Other combinations can also exist according to one or more embodiments.

The active region in the GaN LEDs comprises indium, gallium, and nitrogen. In some embodiments, the active region comprises aluminum. In some embodiments, the device structure in at least one of the LEDs comprises a heterobarrier. In some embodiments, the back surface of the LED is roughened to improve the light extraction efficiency. In one specific embodiment, roughening of the back surface of the LED is performed by photoelectrochemical wet etching. In some embodiments, the substrate for the LED is thinned to improve the light extraction efficiency. In one specific embodiment, thinning of the substrate for the LED comprises at least one of dry-etching, wet-etching (in conjunction with an etch-stop or etch-susceptible layer, respectively), and high-precision chemical-mechanical polishing.

Depending upon the embodiment, the present invention provides methods and devices including any of the above combinations copackaged with Si ICs and/or light detecting devices to form a feedback loop for applications, such as dynamic color tuning where the currents through the various colored LEDs are tuned for given applications such as:

a. Long term maintenance of a high quality white spectrum. This would require some sort of feedback loop, possibly based on some sort of photodetector array that can sense when light intensity is becoming weak in a particular spectral range and then adjust the currents to counteract the degradation.

b. RGB displays where LEDs compose the individual pixels in the display. Since the color of the pixel must be a specific color at a specific instant based on the video signal, there must be an integrated circuit to tune the LED currents to provide the proper color. By copackaging a large array of RGB LEDs with such an IC, we could have a full-color display.

c. Decorative lighting for Christmas lights, building and other aesthetic lighting purposes. These lighting applications would benefit from smart logic.

d. Any application where feedback is required. Such applications include motion sensors, noise sensors, temperature sensors, etc. Of course, there can be other variations, modifications, and alternatives.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1a is a simplified diagram of a copackaged nonpolar blue and semipolar yellow GaN LED chips according to an embodiment of the present invention;

FIG. 1b is a simplified diagram of an alternative copackaged nonpolar GaN blue LED, semipolar GaN green LED, and semipolar GaN red LED according to an embodiment of the present invention;

FIG. 2a is a simplified diagram of yet an alternative copackaged polar GaN blue chip and semipolar yellow GaN LED chips according to a specific embodiment;

FIG. 2b is a simplified diagram of yet an alternative copackaged polar GaN blue LED, semipolar GaN green LED, and semipolar GaN red LED according to a specific embodiment;

FIG. 3a is a simplified diagram of yet an alternative copackaged nonpolar GaN blue LED and AlInGaP yellow LED chips according to a specific embodiment;

FIG. 3b is a simplified diagram of an alternative copackaged nonpolar GaN blue LED, semipolar GaN green LED, and red AlInGaP LED according to an embodiment of the present invention;

FIG. 4 is a simplified diagram of an alternative copackaged polar GaN blue LED, semipolar GaN green LED, and red AlInGaP LED according to an embodiment of the present invention;

FIG. 5 is a simplified diagram of a silicon integrated circuit copackaged with any combination of the LED configurations shown in the previous figures with polar GaN LEDs, semipolar GaN LEDs, and As or P containing LEDs according to an embodiment of the present invention;

FIG. 6 is a simplified diagram of a silicon integrated circuit with logic input capabilities copackaged with any combination of the LED configurations shown in the previous figures with polar GaN LEDs, semipolar GaN LEDs, and As or P containing LEDs according to a specific embodiment;

FIG. 7 is a simplified diagram of a silicon integrated circuit copackaged with wavelength sensitive light detecting devices such as semiconductor photodetectors and any combination of the LED configurations shown in the previous figures with polar GaN LEDs, semipolar GaN LEDs, and As or P containing LEDs according to a specific embodiment;

FIG. 8 is a simplified diagram of wavelength sensitive light detecting devices such as photodiodes monolithically integrated on the same chip as the colored LEDs according to a specific embodiment; and

FIG. 9 is a simplified diagram of a monolithically integrated LED and PD such that PD absorbs fraction of light from LED and provides feedback in the form of photocurrent about light intensity from LED(s) according to a specific embodiment.

### DETAILED DESCRIPTION OF THE SPECIFIC EMBODIMENTS

The present invention relates generally to lighting techniques. More specifically, embodiments of the invention include techniques for combining different colored LED devices, such as blue and yellow, fabricated on bulk semipolar or nonpolar materials. Merely by way of example, the invention can be applied to applications such as white lighting, multi-colored lighting, lighting for flat panel display, other optoelectronic devices, and the like.

Recent breakthroughs in the field of GaN-based optoelectronics have demonstrated the great potential of devices fabricated on bulk nonpolar and semipolar GaN substrates. The lack of strong polarization induced electric fields that plague conventional devices on c-plane GaN leads to a greatly enhanced radiative recombination efficiency in the light emitting InGaN layers. Furthermore, the nature of the electronic band structure and the anisotropic in-plane strain leads to highly polarized light emission, which will offer several advantages in applications such as display backlighting.

Of particular importance to the field of lighting is the progression of light emitting diodes (LED) fabricated on nonpolar and semipolar GaN substrates. Such devices making use of InGaN light emitting layers have exhibited record output powers at extended operation wavelengths in the blue region (430-490 nm), the green region (490-560 nm), and the yellow region (560-600 nm). One promising semipolar orientation is the (11-22) plane. This plane is inclined by 58.4 degrees with respect to the c-plane. University of California, Santa Barbara has produced highly efficient LEDs on (11-22) GaN with over 65 mW output power at 100 mA for blue-emitting devices [1], over 35 mW output power at 100 mA for blue-green emitting devices [2], over 15 mW of power at 100 mA for green-emitting devices [3], and over 15 mW for yellow devices [4]. In [3] it was shown that the indium incorporation on semipolar (11-22) GaN is comparable to or greater than that of c-plane GaN, which provides further promise for achieving high crystal quality extended wavelength emitting InGaN layers.

This rapid progress of semipolar GaN-based emitters at longer wavelengths indicates the imminence of a yellow LED operating in the 570-600 nm range and/or possibly even a red LED operating at wavelengths up to 700 nm on semipolar GaN substrates. Either of these breakthroughs would facilitate a white light source using only GaN based LEDs. In the first case, a blue nonpolar or semipolar LED can be combined with a yellow semipolar LED to form a fully GaN/InGaN-based LED white light source. In the second case, a blue nonpolar or semipolar LED can be combined with a green semipolar LED and a red semipolar LED to form a fully GaN/InGaN-based LED white light source. Both of these technologies would be revolutionary breakthroughs since the inefficient phosphors used in conventional LED based white light sources can be eliminated. Very importantly, the white light source would be highly polarized relative to LED/phosphor based sources, in which the phosphors emit randomly polarized light. Furthermore, since both the blue and the yellow or the blue, green, and red LEDs will be fabricated from the same material system and on the same substrate orientation, great fabrication flexibilities can be afforded by way of monolithic integration of the various color LEDs.

It is important to note that there are several semipolar orientations of possible interest such as the (10-1-1) growth plane. White light sources realized by combining blue and yellow, blue, green, and red, or blue, green, yellow, and red semipolar LEDs would offer great advantages in applications where high efficiency or polarization are important. Such applications include conventional lighting of homes and businesses, decorative lighting, and backlighting for displays. White light sources with three, or, particularly, four or more LEDs will have an improved color-rendering index (CRI), making for more-pleasing sources for general illumination applications. There are several embodiments for this invention including copackaging discrete blue-yellow, blue-green-red LEDs, or blue-green-yellow-red LEDs onto a substrate, for example, a heat sink, or monolithically integrating them on the same chip in a side-by-side configuration, in a stacked junction configuration, or by putting multi-color quantum wells or bulk emitting layers in the same active region. The emitting layer (i.e. InGaN layers) composition and/or quantum well thickness can be adjusted to provide the desired emission wavelength in the said layers. In other embodiments, nitride-based blue, green, and/or yellow LEDs are co-packaged with red AlInGaP LEDs.

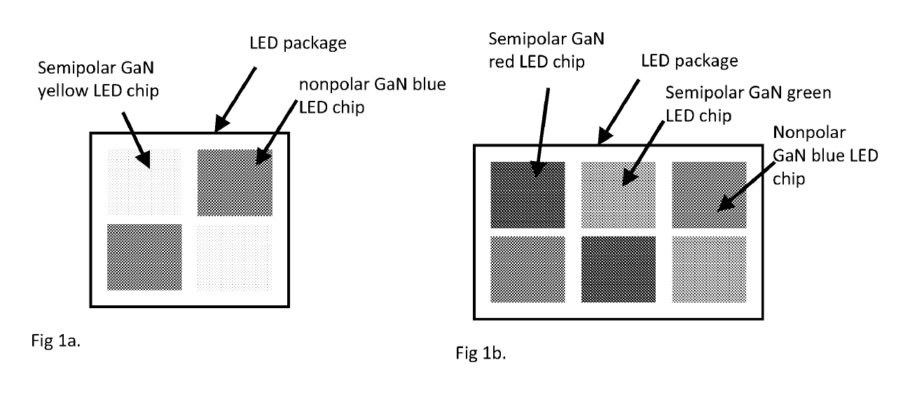

FIG. 1a is a simplified diagram of a copackaged nonpolar blue and semipolar yellow GaN LED chips according to an embodiment of the present invention. The nonpolar may be the yellow and the semipolar may be the blue or both are the same. In a specific embodiment, the LEDs may include one or more of each color LEDs for proper color rendering. In a specific embodiment, each of the LEDs may be electrically wired in parallel or series or independently.

FIG. 1b is a simplified diagram of an alternative copackaged nonpolar GaN blue LED, semipolar GaN green LED, and semipolar GaN red LED according to an embodiment of the present invention. Depending upon the embodiment, the LEDs may be any combination of nonpolar and semipolar LEDs. In a specific embodiment, the LEDs may be one or more of each color LEDs for proper color rendering. In a specific embodiment, each of the LEDs may also be electrically wired in parallel or series or independently. Of course, there could be other variations, modifications, and alternatives.

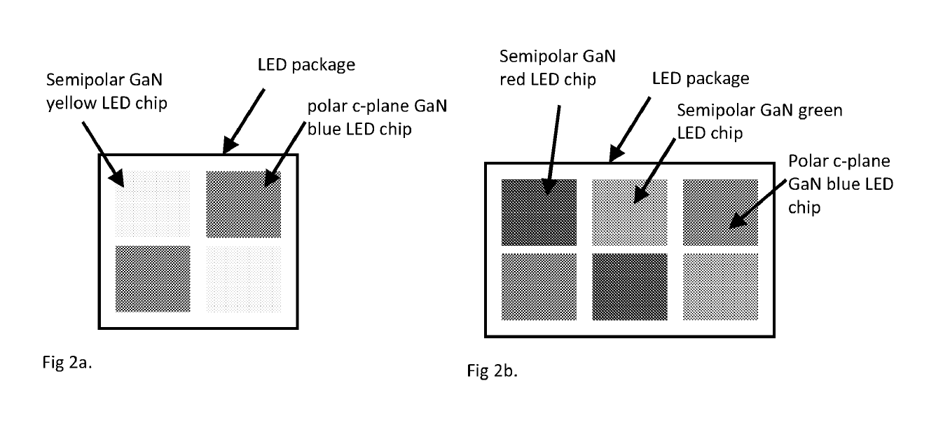

FIG. 2a is a simplified diagram of yet an alternative copackaged polar GaN blue chip and semipolar yellow GaN LED chips according to a specific embodiment. As an example, the semipolar chip could be nonpolar GaN. In a specific embodiment, the polar GaN may be the yellow and the semipolar could be the blue or both may be the same according to a specific embodiment. In a specific embodiment, the LEDs may be one or more of each color LEDs for proper color rendering. In a specific embodiment, the LEDs may also be electrically wired in parallel or series or independently according to a specific embodiment.

FIG. 2b is a simplified diagram of yet an alternative copackaged polar GaN blue LED, semipolar GaN green LED, and semipolar GaN red LED according to a specific embodiment. In a specific embodiment, the LEDs may include any combination of polar, nonpolar, and semipolar LEDs. Depending upon the embodiment, the LEDs may also be one or more of each color LEDs for proper color rendering. Additionally, each of the LEDs may be electrically wired in parallel or series or independently according to a specific embodiment.

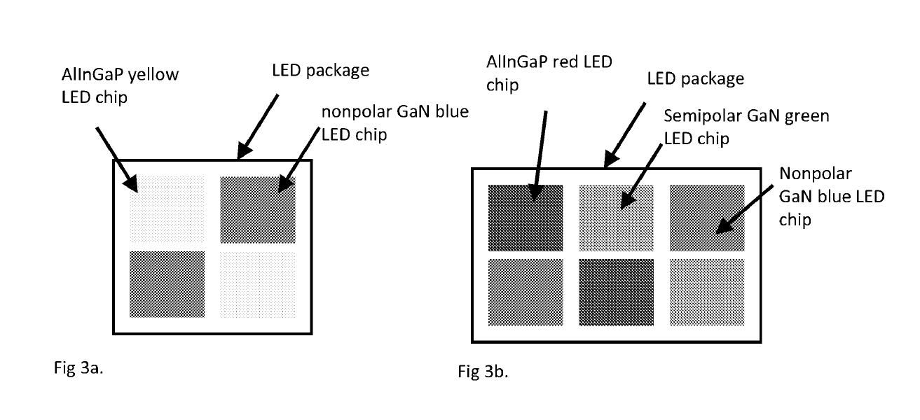

FIG. 3a is a simplified diagram of yet an alternative copackaged nonpolar GaN blue LED and AlInGaP yellow LED chips according to a specific embodiment. The nonpolar LED chip may be replaced with a semipolar LED chip according to a specific embodiment. Depending upon the embodiment, the LEDs may also be one or more of each color LEDs for proper color rendering. Of course, each of the LEDs may also be electrically wired in parallel or series or independently according to a specific embodiment.

FIG. 3b is a simplified diagram of an alternative copackaged nonpolar GaN blue LED, semipolar GaN green LED, and red AlInGaP LED according to an embodiment of the present invention. In a specific embodiment, the LEDs may be any combination of nonpolar, semipolar, and As or P based LED. Depending upon the embodiment, the LEDs may also be one or more of each color LEDs for proper color rendering. Each of the LEDs may also be electrically wired in parallel or series or independently according to a specific embodiment.

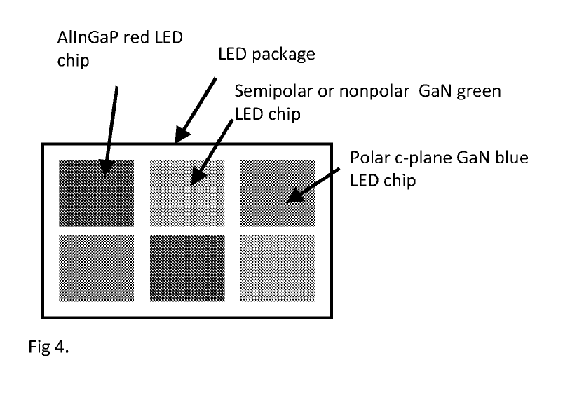

FIG. 4 is a simplified diagram of an alternative copackaged polar GaN blue LED, semipolar GaN green LED, and red AlInGaP LED according to an embodiment of the present invention. In a specific embodiment, the LEDs may be any combination of polar, nonpolar, semipolar, and As or P based LED. In a specific embodiment, the LEDs may also be one or more of each color LEDs for proper color rendering. Depending upon the embodiment, each of the LEDS may be electrically wired in parallel or series or independently.

Referring now to the Figures below, we intend to describe the various copackaging configurations of the previous five slides in combination with Si ICs and wavelength sensitive or perhaps not wavelength sensitive light detecting devices according to a specific embodiment. In a specific embodiment, the copackaging configuration includes a reverse biased photodiode (PD) as the light sensing device. Depending upon the specific embodiment, the LED and light sensing photodiode device are monolithically integrated. In a specific embodiment, the packaging may be one of a plurality of standard designs in different shapes and sizes. In a specific embodiment, the LED is forward biased and the photodiode is reverse biased. Of course, there can be other variations, modifications, and alternatives.

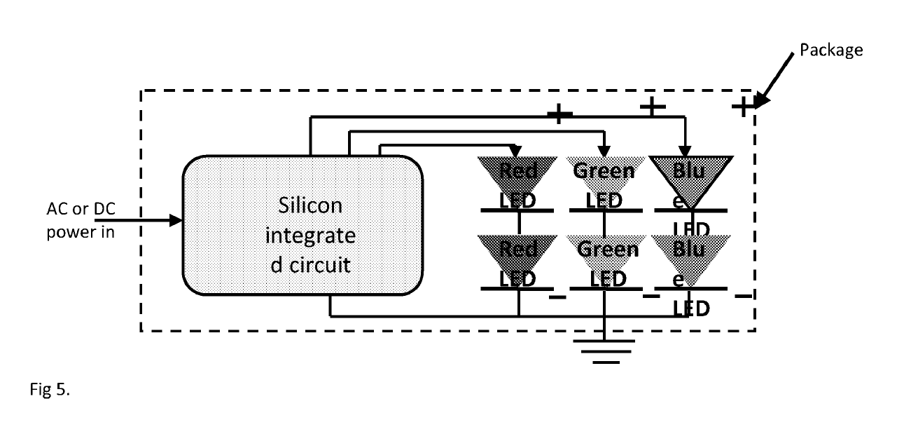

FIG. 5 is a simplified diagram of a silicon integrated circuit copackaged with any combination of the LED configurations shown in the previous figures with polar GaN LEDs, semipolar GaN LEDs, and As or P containing LEDs according to an embodiment of the present invention. In a specific embodiment, one or more of each color LEDs is for proper color rendering is included. In a specific embodiment, the silicon IC functions to tune and/or adjust the currents (and power) to the various or one or more LEDs to achieve desired color output to be used in a display or decorative light device. The IC drives one or more of each color LEDs in series according to a specific embodiment. Furthermore, the IC may drive many channels of the RGB or blue-yellow LED combinations for more complex device such as displays according to a specific embodiment.

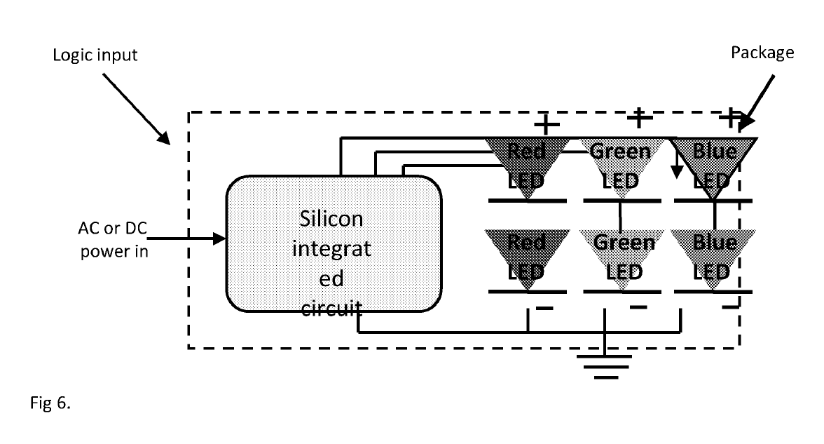

FIG. 6 is a simplified diagram of a silicon integrated circuit with logic input capabilities copackaged with any combination of the LED configurations shown in the previous figures with polar GaN LEDs, semipolar GaN LEDs, and As or P containing LEDs according to a specific embodiment. One or more of each color LEDs for proper color rendering is included. In a specific embodiment, the silicon IC functions to tune and/or adjust the currents (and power) to the various or one or more LEDs to achieve desired color output to be used in a display or decorative light device. The IC drives one or more of each color LEDs in series according to a specific embodiment. Furthermore, the IC may also be driving many or one or more channels of the RGB or blue-yellow LED combinations for more complex device such as displays according to a specific embodiment.

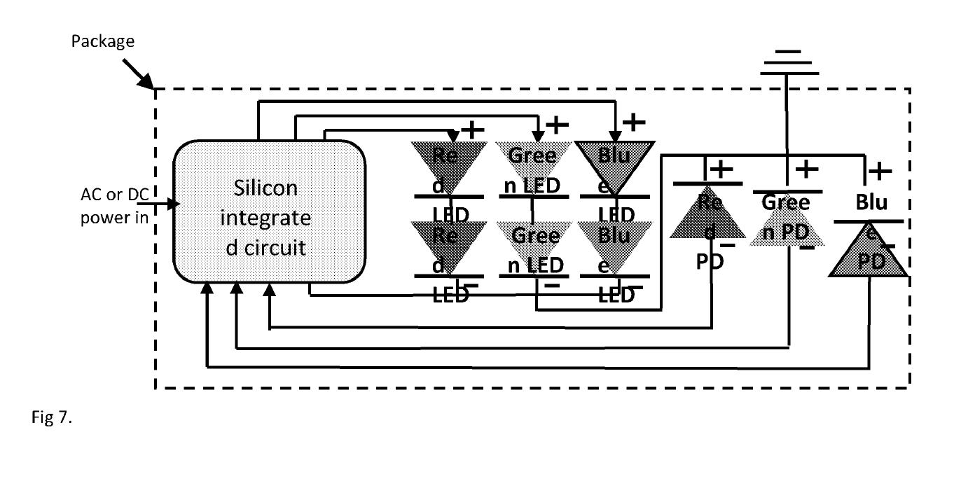

FIG. 7 is a simplified diagram of a silicon integrated circuit copackaged with wavelength sensitive light detecting devices such as semiconductor photodetectors and any combination of the LED configurations shown in the previous figures with polar GaN LEDs, semipolar GaN LEDs, and As or P containing LEDs according to a specific embodiment. One or more of each color LEDs for proper color rendering is included. In a specific embodiment, the LEDs may be RGB or blue and yellow LEDs. The silicon IC along with feedback provided by sensing devices functions to tune the currents and/or power to the various or one or more LEDs to achieve desired color output to be used in a display or decorative light device according to a specific embodiment. The IC may be driving one or more of each color LEDs in series according to a specific embodiment. Furthermore, the IC drives many channels or one or more channels of the RGB or blue-yellow LED combinations for more complex device such as displays according to a specific embodiment.

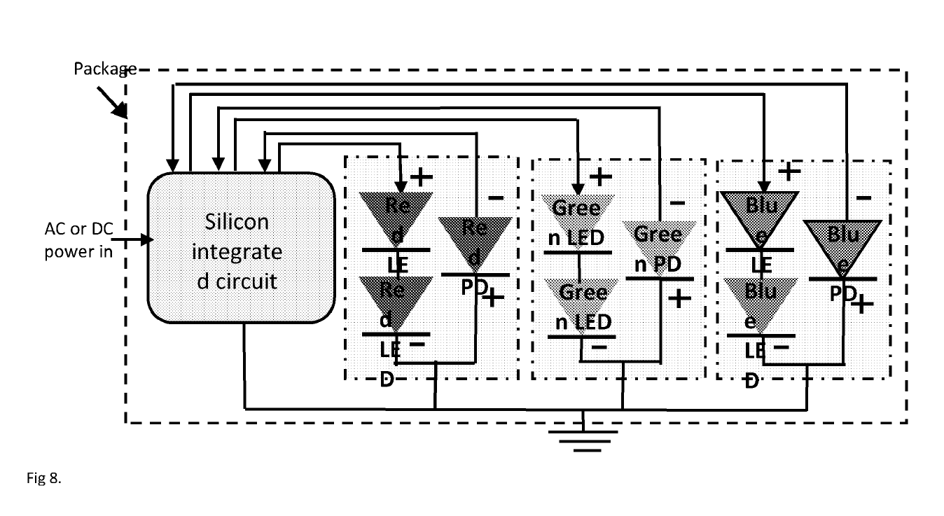

FIG. 8 is a simplified diagram of wavelength sensitive light detecting devices such as photodiodes monolithically integrated on the same chip as the colored LEDs according to a specific embodiment. Under forward bias the p-i-n junction emits light, under reverse bias it detects light and converts the photons into electrons resulting in a photocurrent that is fed back into the silicon IC as the feedback signal to tune the output current for a desired effect according to a specific embodiment. This feedback effect can be enhanced if quantum well are used in the intrinsic (i) region since exitonic absorption should give a sharp absorption peak at the bandgap energy of the adjacent emitter device. Furthermore, since the PD and LED are in close vicinity, the detected photocurrent will be dominated by the adjacent LED opposed to the other LEDs in the package according to a specific embodiment.

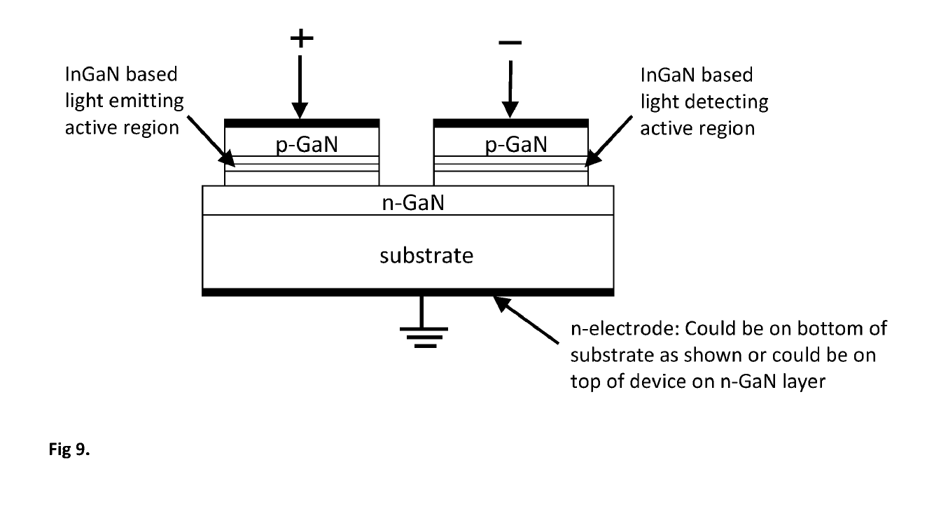

FIG. 9 is a simplified diagram of a monolithically integrated LED and PD such that PD absorbs fraction of light from LED and provides feedback in the form of photocurrent about light intensity from LED(s) according to a specific embodiment. A copackaged Si IC can adjust current to LED to adjust light output for output for a desired effect according to a specific embodiment. The LED is forward biased and the PD is reverse biased according to a specific embodiment.

As used herein as an example, the terms GaN containing substrates or GaN substrates or more generally gallium and nitrogen containing substrates are associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k l) plane wherein h=k=0, and l is non-zero), non-polar GaN substrates (i.e., substrate material where the largest area surface is oriented at an angle ranging from about 80-100 degrees from the polar orientation described above towards an (h k l) plane wherein l=0, and at least one of h and k is non-zero) or semi-polar GaN substrates (i.e., substrate material where the largest area surface is oriented at an angle ranging from about +0.1 to 80 degrees or 110-179.9 degrees from the polar orientation described above towards an (h k l) plane wherein l=0, and at least one of h and k is non-zero). Of course, there can be other interpretations consistent with one of ordinary skill in the art.

While the above is a full description of the specific embodiments, various modifications, alternative constructions and equivalents may be used. Therefore, the above description and illustrations should not be taken as limiting the scope of the present invention which is defined by the appended claims.

### CITED PUBLICATIONS

[1] H. Zhong, A. Tyagi, N. N. Fellows, F. Wu, R. B. Chung, M. Saito, K. Fujito, J. S. Speck, S. P. DenBaars, and S. Nakamura, “High power and high efficiency blue light emitting diode on freestanding semipolar (11-22) bulk GaN substrate,” Appl. Phys. Lett., vol. 90, 2007.
[2] H. Sato, A. Tyagi, H. Zhong, N. Fellows, R. Chung, M. Saito, K. Fujito, J. Speck, S. DenBaars, and S. Nakamura, “High power and high efficiency green light emitting diode on free-standing semipolar (11-22) bulk GaN substrate,” Phys. Stat. Sol. (RRL), vol. 1, pp. 162-164, June 2007.
[3] H. Zhong, A. Tyagi, N. N. Fellows, R. B. Chung, M. Saito, K. Fujito, J. S. Speck, S. P. DenBaars, and S. Nakamura, “Demonstration of high power blue-green light emitting diode on semipolar (1122) bulk GaN substrate,” Elect. Lett., vol. 43, pp. 825-826.
[4] H. Sato,_R. B. Chung, H. Hirasawa, N. Fellows, H. Masui, F. Wu, M. Saito, K. Fujito,_J. S. Speck, S. P. DenBaars, and S. Nakamura, “Optical properties of yellow light-emitting-diodes grown on semipolar (11-22) bulk GaN substrate,” Appl. Phys. Lett., vol. 92, 2008.

Each of the cited publication is hereby incorporated by reference herein. While the above is a full description of the specific embodiments, various modifications, alternative constructions and equivalents may be used. Therefore, the above description and illustrations should not be taken as limiting the scope of the present invention which is defined by the appended claims.

What is claimed is:

1. A packaged light emitting device comprising:
a substrate member comprising a surface region;
two or more light emitting diode devices overlying the surface region, at least a first of the light emitting diode device being fabricated on a semipolar gallium and nitrogen containing substrate and at least a second of the light emitting diode devices being fabricated on a nonpolar gallium and nitrogen containing substrate, the two or more light emitting diode devices emits substantially polarized emission.

2. The device of claim 1 wherein the first of the light emitting diode devices comprising a blue LED device and the second of the light emitting diode devices comprising a yellow LED device, the substantially polarized emission being white light.

3. The device of claim 1 wherein the first of the light emitting diode devices comprising a yellow LED device and the second of the light emitting diode devices comprising a blue LED device, the substantially polarized emission being white light.

4. The device of claim 1 wherein the two or more light emitting diode device comprises an array of LED devices comprising a pair of blue LED devices and a pair of yellow LED devices.

5. The device of claim 1 wherein the two or more light emitting diode devices comprises at least a red LED device, a blue LED device, and a green LED device.

6. The device of claim 1 wherein the two or more light emitting diode devices comprises at least a red LED device, a blue LED device, a yellow LED device, and a green LED device.

7. The device of claim 1 further comprising an Nth LED device, the Nth LED device being fabricated on an arsenide or phosphide containing substrate.

8. The device of claim 7 wherein the phosphide containing substrate is derived from an AlInGaP containing material.

9. The device of claim 1 further comprising further comprising an integrated circuit device, the integrated circuit device being fabricated on a silicon containing substrate.

10. A packaged light emitting device comprising:
a substrate member comprising a surface region;
two or more light emitting diode devices overlying the surface region, at least a first of the light emitting diode device being fabricated on a semipolar gallium and nitrogen containing substrate and at least a second of the light emitting diode devices comprising a polar gallium and nitrogen containing device.

11. The device of claim 10 wherein the first of the light emitting diode devices comprising a blue LED device and the second of the light emitting diode devices comprising a yellow LED device.

12. The device of claim 10 wherein the first of the light emitting diode devices comprising a yellow LED device and the second of the light emitting diode devices comprising a blue LED device.

13. The device of claim 10 wherein the two or more light emitting diode devices comprise an array of LED devices.

14. The device of claim 10 wherein the two or more light emitting diode devices comprises at least a red LED device, a blue LED device, and a green LED device.

15. The device of claim 10 wherein the two or more light emitting diode devices comprises at least a red LED device, a blue LED device, a yellow LED device, and a green LED device.

16. The device of claim 10 further comprising an Nth LED device, the Nth LED device being fabricated on an arsenide or phosphide containing substrate.

17. The device of claim 16 wherein the phosphide containing substrate is derived from an AlInGaP containing material.

18. The device of claim 10 further comprising further comprising an integrated circuit device, the integrated circuit device being fabricated on a silicon containing substrate.

19. A packaged light emitting device comprising:
a substrate member comprising a surface region;
two or more light emitting diode devices overlying the surface region, at least a first of the light emitting diode device being fabricated on a non-polar gallium and nitrogen containing substrate and at least a second of the light emitting diode devices comprising a polar gallium and nitrogen containing device.

20. The device of claim 19 wherein the first of the light emitting diode devices comprising a blue LED device and the second of the light emitting diode devices comprising a yellow LED device.

21. The device of claim 19 wherein the first of the light emitting diode devices comprising a yellow LED device and the second of the light emitting diode devices comprising a blue LED device.

22. The device of claim 19 wherein the two or more light emitting diode devices comprise an array of LED devices.

23. The device of claim 19 wherein the two or more light emitting diode devices comprises at least a red LED device, a blue LED device, and a green LED device.

24. The device of claim 19 wherein the two or more light emitting diode devices comprises at least a red LED device, a blue LED device, a yellow LED device, and a green LED device.

25. The device of claim 19 further comprising an Nth LED device, the Nth LED device being fabricated on an arsenide or phosphide containing substrate.

26. The device of claim 25 wherein the phosphide containing substrate is derived from an AlInGaP containing material.

27. The device of claim 19 further comprising further comprising an integrated circuit device, the integrated circuit device being fabricated on a silicon containing substrate.

28. A packaged light emitting device comprising:
a substrate member comprising a surface region;
two or more light emitting diode devices overlying the surface region, at least a first of the light emitting diode device being fabricated on a semi-polar gallium and nitrogen containing substrate and at least a second of the light emitting diode devices being fabricated on a semi-polar gallium and nitrogen containing substrate.

29. The device of claim 28 wherein the first of the light emitting diode devices comprising a blue LED device and the second of the light emitting diode devices comprising a yellow LED device.

30. The device of claim 28 wherein the two or more light emitting diode devices comprise an array of LED devices.

31. The device of claim 28 wherein the two or more light emitting diode devices comprises at least a red LED device, a blue LED device, and a green LED device.

32. The device of claim 28 wherein the two or more light emitting diode devices comprises at least a red LED device, a blue LED device, a yellow LED device, and a green LED device.

33. The device of claim 28 further comprising an Nth LED device, the Nth LED device being fabricated on an arsenide or phosphide containing substrate.

34. The device of claim 33 wherein the phosphide containing substrate is derived from an AlInGaP containing material.

35. The device of claim 28 further comprising further comprising an integrated circuit device, the integrated circuit device being fabricated on a silicon containing substrate.

36. A packaged light emitting device comprising:
a substrate member comprising a surface region;
two or more light emitting diode devices overlying the surface region, at least a first of the light emitting diode device being fabricated on a non-polar gallium and nitrogen containing substrate and at least a second of the light emitting diode devices being fabricated on a non-polar gallium and nitrogen containing substrate.

37. The device of claim 36 wherein the first of the light emitting diode devices comprising a blue LED device and the second of the light emitting diode devices comprising a yellow LED device.

38. The device of claim 36 wherein the two or more light emitting diode devices comprise an array of LED devices.

39. The device of claim 36 wherein the two or more light emitting diode devices comprises at least a red LED device, a blue LED device, and a green LED device.

40. The device of claim 36 wherein the two or more light emitting diode devices comprises at least a red LED device, a blue LED device, a yellow LED device, and a green LED device.

41. The device of claim 36 further comprising an Nth LED device, the Nth LED device being fabricated on an arsenide or phosphide containing substrate.

42. The device of claim 41 wherein the phosphide containing substrate is derived from an AlInGaP containing material.

43. The device of claim 36 further comprising further comprising an integrated circuit device, the integrated circuit device being fabricated on a silicon containing substrate.
